(19) United States
(12) Patent Application Publication
(10) Pub. No.: US 2015/0055288 A1
(43) Pub. Date: Feb. 26, 2015

(54) SERVER

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: JING-FU ZHANG, Shenzhen (CN); QIANG CHAI, Shenzhen (CN)

(21) Appl. No.: 14/465,399

(22) Filed: Aug. 21, 2014

(30) Foreign Application Priority Data
Aug. 26, 2013 (CN) 201310374079X

(51) Int. Cl. H05K 9/00; H05K 7/20; H05K 7/14

(52) U.S. Cl. CPC H05K 9/002; H05K 7/1488; H05K 7/20709
USPC 361/679.33

(57) ABSTRACT

A shield against electromagnetic radiation emanating from a server includes a shielding apparatus attached to a server chassis which contains a set of hard disk drive modules. Each hard disk drive module includes a bracket and a hard disk drive fixed therein. A gap is defined between one end of each bracket and the hard disk drive held in the bracket. The gaps of the brackets extend from top to bottom. The top plate of the chassis defines a slot corresponding to the gaps. The shielding apparatus includes a mounting plate and a set of spaced shielding units set vertically to the mounting plate. Each shielding unit defines a set of electrically-conductive vents functioning as waveguides to absorb electromagnetic radiation.

### FIELD

The subject matter herein generally relates to shielding against electromagnetic interference.

### BACKGROUND

A sever can includes a number of hard disk drives installed therein. A gap between the hard disk drives and brackets receiving the hard disk drives may allow electromagnetic radiation leakage.

### BRIEF DESCRIPTION OF THE DRAWINGS

Implementations of the present technology will now be described, by way of example only, with reference to the attached figures, wherein:

FIG. 1 is an exploded, isometric view of an embodiment of a server.

FIG. 2 is an isometric view of a shielding apparatus of the server in FIG. 1.

FIG. 3 is an enlarged view of circled portion III of FIG. 2, which is a first embodiment of a shielding unit.

FIGS. 4 and 5 are assembled, isometric views of the server of FIG. 1.

FIG. 6 is an isometric view of a second embodiment of a shielding unit.

FIG. 7 is an isometric view of a third embodiment of a shielding unit.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiment described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “comprising,” when utilized, means “including, but not necessarily limited to”; it specifically indicates open-ended inclusion or membership in the so-described combination, group, series and the like.

The present disclosure describes a server.

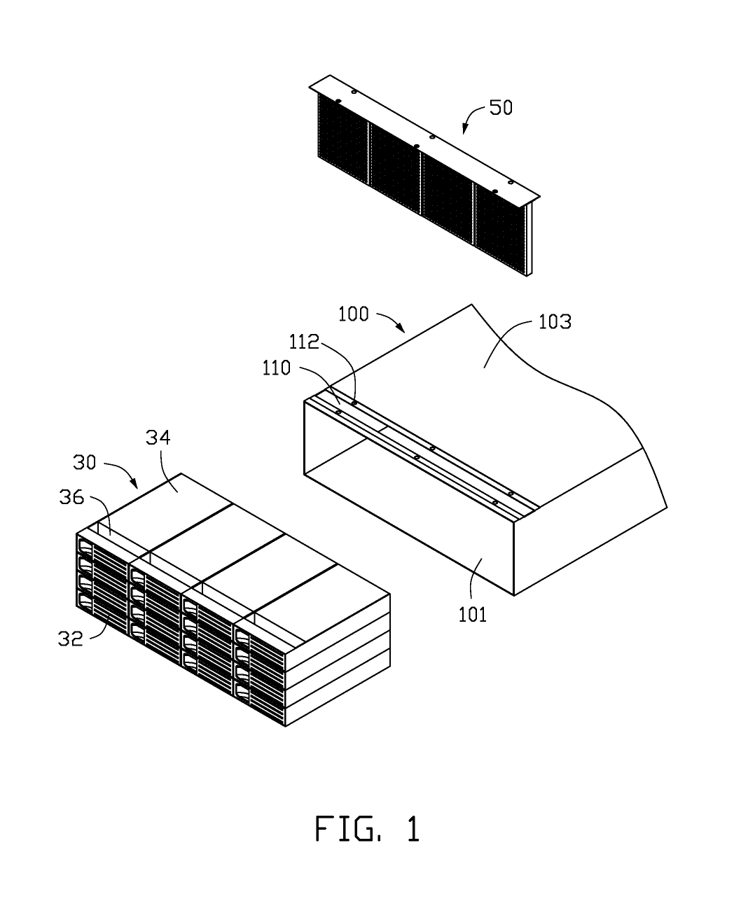

FIG. 1 illustrates an embodiment of a server which includes a chassis 100, a set of hard disk drive modules 30 installed in the chassis 100, and a shielding apparatus 50.

The chassis 100 defines an opening 101 in a front end and a slot 110 in a top plate 103 of the chassis 100 adjacent to the opening 101. The chassis 100 defines a set of screw holes 112 in the top plate 103 beside the two sides of the slot 110.

Each hard disk drive module 30 comprises a bracket 32 and a hard disk drive 32 mounted therein. A gap 36 is defined between a front end of the hard disk drive 34 and a front portion of the bracket 32.

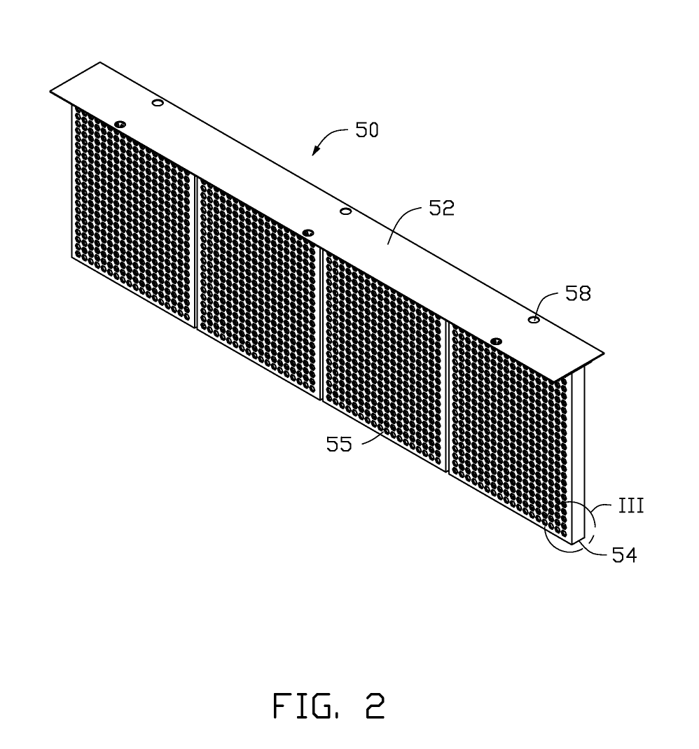

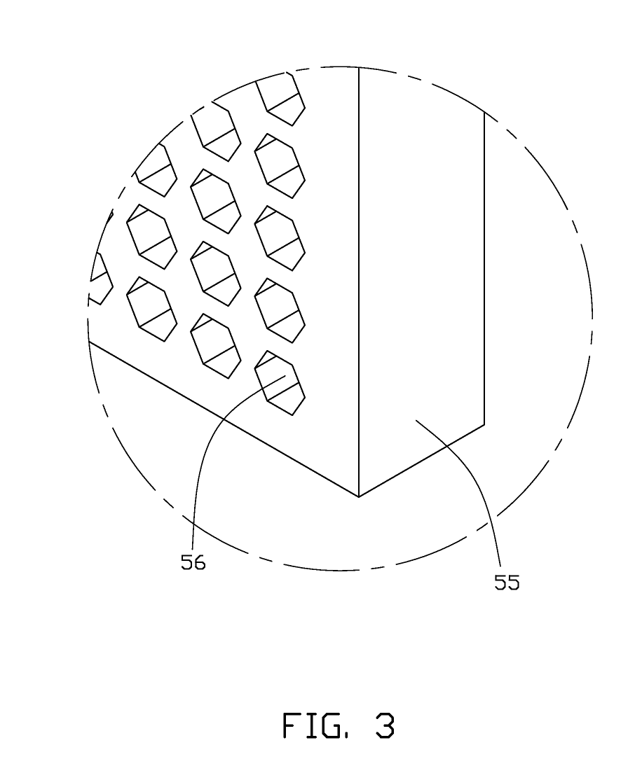

FIGS. 2 and 3 illustrate that the shielding apparatus 50 comprises a mounting plate 52 and a set of spaced shielding units 54 vertically extending from a bottom of the mounting plate 52. The mounting plate 52 defines a set of through holes 58 along two sides thereof. Each shielding unit 54 comprises a shielding plate 55. A set of lateral vents 56 is defined in the shielding plate 55, extending through the shielding plate 55. A conductive layer is continuously formed on surfaces bounding each vent 56. The conductive layer can be made of metal, such as nickel or tin applied by plating. In the embodiment, each vent 56 is a regular hexagon. In other embodiments, the vents 56 can be round, rectangular or other shapes. The vents 56 can be a single shape and size or multiple different shapes and sizes, and can be spaced at fixed or variable distances from each other.

Each vent 56 can be a waveguide with a cut-off frequency. The cut-off frequency of the waveguide can be regulated by adjusting the thickness of the shielding plate 55 and an internal diameter of the vent 56.

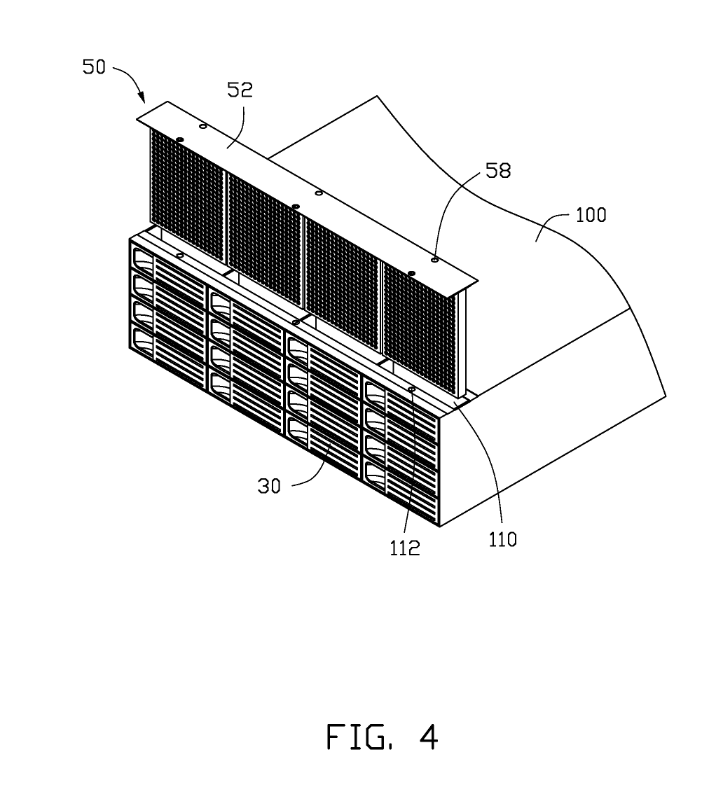

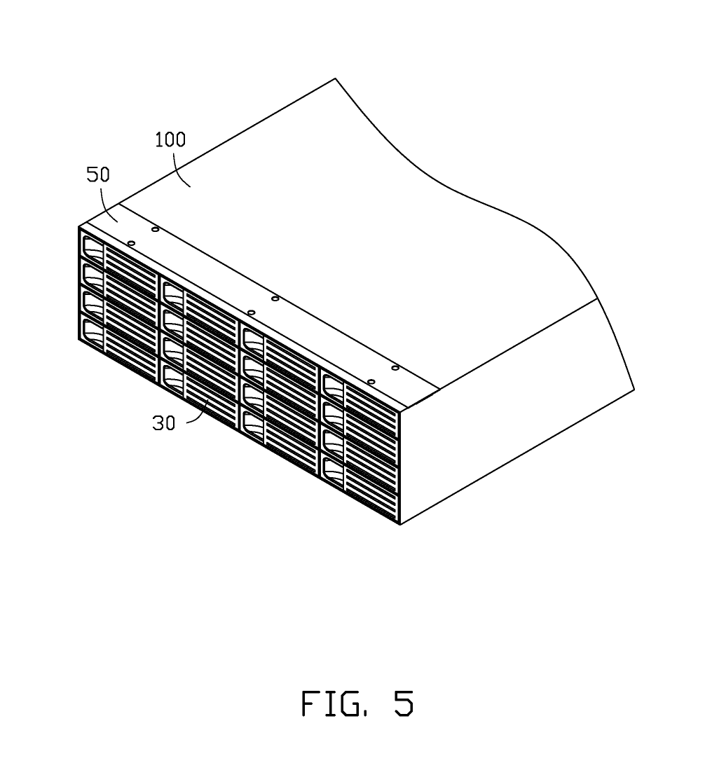

FIGS. 4 and 5 show that in assembly, the hard disk drive modules 30 are inserted into the chassis 100 through the opening 10. The hard disk drive modules 30 are stacked in groups of four and the gaps 36 of each group of hard disk drive modules 30 are aligned, and the gaps 36 are in alignment with the slot 110. The shielding plates 55 of the shielding apparatus 50 are received in the gaps 36 through the slot 110, the mounting plate 52 abutting the top plate 103 of the slot 110. Screws extend through the through holes 58 and engage in the screw holes 112, to fasten the shielding apparatus 50 to the chassis 100.

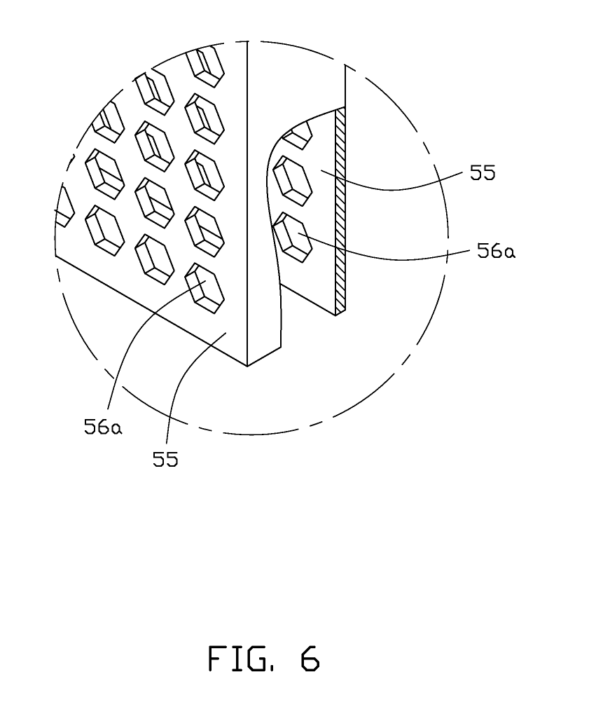

FIG. 6 illustrates a second embodiment of the shielding unit. The shielding unit 54 comprises two parallel and spaced shielding plates 55 to form a cavity or space between the shielding plates 55. A set of pairs of aligned vents 56a is defined in the two shielding plates 55. A conductive layer is continuously formed on the surface bounding each vent. Each pair of aligned vents 56a forms a waveguide. In one specific example embodiment, each aligned vent 56a is a regular hexagon and a distance between the two shielding plates 55 is 10 mm.

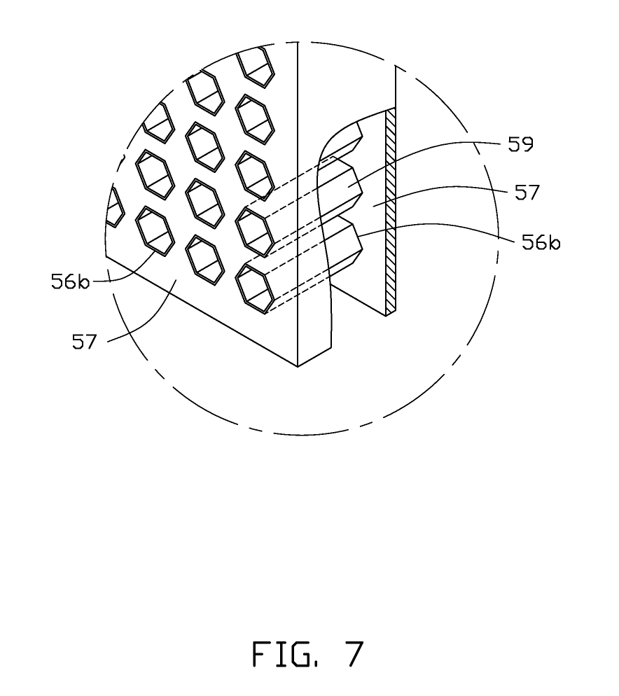

FIG. 7 illustrates a third embodiment of the shielding unit. The shielding unit 54 comprises two parallel and spaced shielding plates 57. A set of pairs of vents 56b is defined in the two shielding plates 57 and a tube 59 is connected between each pair of vents 56b. A conductive layer is continuously formed on surfaces bounding each vent 56 and on the inner surfaces of the tubes 59. Each pair of vents 56b and the tube 59 connected therebetween form a waveguide. In the third embodiment, the vent 56b and a cross section of the tube 59 are regular hexagons and a distance between the two shielding plates 57 is 10 mm, although other distances and hexagon sizes can be selected for different types of radiation, for example.

The shielding apparatus 50 is inserted between the hard disk drives 34 and the brackets 32. The vents 56, 56a, and 56b, together with the tubes 59, function as waveguides, to cancel electromagnetic radiation leakage from the hard disk drive modules 30. The example shows a single shielding apparatus 50 in the chassis, but one or more shielding apparatus 50 can be used on the same chassis. The shielding apparatus can be rectangular or some other shape to accommodate different chassis shapes.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A server, comprising:
a chassis comprising a top plate, a slot defined in the top plate;
a plurality of hard disk drive modules received in the chassis, each hard disk drive module comprising a bracket and a hard disk drive fixed therein, a gap defined between the bracket and the hard disk drive, the hard disk drive modules stacked into a plurality of groups and the gaps of each group of hard disk drive modules in alignment with the slot; and
a shielding apparatus comprising a mounting plate fixed to the top plate of the chassis and a plurality of spaced shielding units extending from the mounting plate and respectively received in the gaps of the groups of the hard disk drive modules, each shielding unit comprising a plurality of waveguides.

2. The server of claim 1, wherein each shielding unit comprises a shielding plate, a plurality of vents is defined in the shielding plate and extends through two opposite sides of the shielding plate, each vent forms a waveguide.

3. The server of claim 2, wherein surfaces bounding each vent are coated with a conductive layer.

4. The server of claim 1, wherein each shielding unit comprises two parallel and spaced shielding plates, a plurality of vents is respectively defined in the two shielding plates, each pair of vents forms a waveguide.

5. The server of claim 4, wherein surfaces bounding each vent are coated with a conductive layer.

6. The server of claim 1, wherein each shielding unit comprises two parallel and spaced shielding plates, a plurality of pairs of vents is respectively defined in the two shielding plates, a tube is connected between each pair of the vents, each pair of vents and the tube connected therebetween forms a waveguide.

7. The server of claim 6, wherein surfaces bounding each vent and inner surfaces of the tube are coated with a conductive layer.

8. The server of claim 2, wherein the vents are regular hexagons.

9. The server of claim 1, wherein the mounting plate defines a plurality of through holes, the top plate defines a plurality of screw holes along two sides of the slot, screws extend through the corresponding through holes and engage in the corresponding screw holes, to fasten the shielding apparatus to the chassis.

10. The server of claim 1, wherein the shielding apparatus is coated with a conductive layer.
